(19) United States
(12) Patent Application Publication
(10) Pub. No.: US 2011/0084355 A1
(43) Pub. Date: Apr. 14, 2011

(54) Isolation Structure For Semiconductor Device

(75) Inventors: Hsien-Hsin Lin, Hsin-Chu City (TW); Bor Chiuan Hsieh, Taoyuan City (TW); Chen-Ping Chen, Toucheng Township (TW)

(73) Assignee: TAIWAN SEMICONDUCTOR MANUFACTURING COMPANY, LTD., Hsin-Chu (TW)

(21) Appl. No.: 12/576,818

(22) Filed: Oct. 9, 2009

(51) Int. Cl. H01L 29/06; H01L 21/762

(52) U.S. Cl. 257/506; 438/400; 257/E29.02; 257/E21.545

(57) ABSTRACT

A semiconductor device is provided. The semiconductor device includes a substrate, an isolation feature disposed on the substrate, and an active area disposed adjacent the isolation feature. The isolation feature may be a shallow trench isolation feature. The STI feature has a first width at the top of the feature and a second width at the bottom of the feature. The first width is less than the second width. Methods of fabricating a semiconductor device is also provided. A method includes forming shallow trench isolation features and then growing an epitaxial layer adjacent the STI features to form an active region.

### BACKGROUND

The semiconductor integrated circuit (IC) industry has experienced rapid growth. In the course of IC evolution, functional density has generally increased while feature size has decreased. Scaling down generally provides benefits by increasing production efficiency and lowering associated costs. As the device density decreases, features are required to be formed at tighter and tighter pitches. For example, as the active areas of a device decrease in pitch, so do the interposing isolation features (e.g., shallow trench isolation (STI)). As the pitch of features decrease, forming such features becomes more challenging. For example, sufficiently filling isolation features such as STI structures may become difficult. Processes used to fill such structures often require numerous processing steps and increased costs.

Accordingly, what is needed is a semiconductor device, and method of fabricating such, that addresses one or more of the above stated issues.

### SUMMARY

In one embodiment, a semiconductor includes a substrate, a shallow trench isolation (STI) structure formed on the substrate, and an active area adjacent the STI structure. The STI structure has a first width at the top of the structure and a second width at the bottom of the structure. The first width is less than the second width.

In one embodiment, a method of fabricating a semiconductor device is provided. The method includes providing a substrate and forming a dielectric layer on the substrate. The dielectric layer is etched forming a first and second shallow trench isolation structures interposed by an exposed substrate region. After etching the dielectric layer, an epitaxial layer is formed in the exposed substrate region. The epitaxial layer may be used to provide an active region of a semiconductor device.

In one embodiment, a method of fabricating a semiconductor device is provided. The method includes providing a substrate and forming a dielectric layer on the substrate. A masking element is formed on the substrate over the dielectric layer. The masking element defines a pattern of a plurality of shallow trench isolation structures. The dielectric layer is etched according to the pattern. The etching process forms a first and a second STI structure. The first and the second STI structures have a greater width at the bottom (e.g., adjacent the substrate) than the top. An area interposes the first and second STI structures. After etching the dielectric layer, an active region is formed in the first area. The active region may be formed by growing an epitaxial layer on the substrate.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a cross-sectional view of an embodiment of a semiconductor device including an active region.

FIG. 2 is a flow chart illustrating an embodiment of a method of forming a semiconductor device including an active region.

FIG. 3 is a flow chart illustrating an embodiment of a method of forming a semiconductor device according to the method of FIG. 2.

FIGS. 4-11 are cross-sectional views of embodiments of a substrate corresponding to one or more steps of the method of FIG. 3.

### DETAILED DESCRIPTION

The present disclosure relates generally to semiconductor device, and more particularly to a semiconductor device including a plurality of active regions disposed therein. It is understood that the following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. Terms such as “top,” “bottom,” “upper,” “lower,” and the like provide a relative description only and are not intended to imply an absolute direction. In addition, the present disclosure may repeat reference numerals and/or letters in the various examples. This repetition is for the purpose of simplicity and clarity and does not in itself dictate a relationship between the various embodiments and/or configurations discussed.

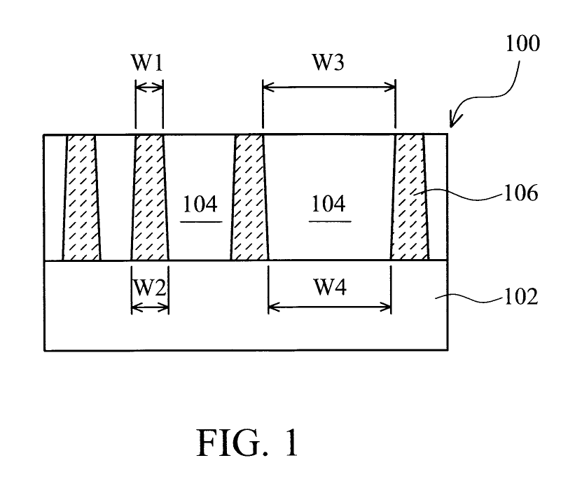

With reference to FIG. 1, illustrated is a semiconductor device 100. The semiconductor device 100 may include passive components such as resistors, capacitors, inductors, and/or fuses; and active components, such as P-channel field effect transistors (PFETs), N-channel field effect transistors (NFETs), metal-oxide-semiconductor field effect transistors (MOSFETs), complementary metal-oxide-semiconductor transistors (CMOSs), high voltage transistors, and/or high frequency transistors; other suitable components; and/or combinations thereof. The semiconductor device 100 includes a substrate 102. In an embodiment, the substrate 102 includes an elementary semiconductor-silicon. Other example compositions of the substrate 102 include germanium in crystal; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; combinations thereof; and/or other suitable substrate materials. In embodiments, the substrate 102 may be a semiconductor on insulator (SOI) substrate, a strained substrate, and/or include other features.

A plurality of isolation regions 106 and active regions (or areas) 104 are disposed on the substrate 102. The active regions 104 may also be referred to as OD areas. The active regions 104 may include regions on the substrate 102 in which transistors and/or other devices are disposed. The isolation regions 106 may be shallow trench isolation (STI) features or other suitable isolation features. The isolation regions 106 include dielectric material such as, TEOS oxide, silicon oxide, silicon nitride, silicon oxynitride, hafnium oxide, zirconium oxide, titanium oxide, aluminum oxide, hafnium dioxide-alumina (HfO₂—Al₂O₃) alloy, PSG, BPSG, other suitable dielectric materials, and/or combinations thereof. In an embodiment, the isolation regions 106 include low-k dielectric material. Examples of low-k dielectric materials include fluorinated silica glass (FSG), doped silicon oxide, Black Diamond, Xerogel, Aerogel, amorphous fluorinated carbon, Parylene, bis-benzocyclobutenes (BCB), SiLK, hydrogen silsesquioxane (HSQ), methyl silsesqioxane (MSQ), and/or combinations thereof.

The active regions 104 may include an epitaxially-grown layer (e.g., by performing an epitaxy process on the substrate 102). In an embodiment, the active regions 104 include epitaxially-grown silicon. The active regions 104 may be doped (e.g., an n-type or p-type dopant impurities) to provide suitable conductivity. Example dopants include n-type dopant impurities such as phosphorus, arsenic, and/or other suitable materials and p-type dopant impurities such as boron, indium, and/or other suitable materials. The active regions 104 may have a gradient doping profile (e.g., the doping profile changes from one location to another, such as a retrograde doping profile). In an embodiment, the gradient doping profile provides for the active regions 104 to be more heavily doped in a region adjacent the substrate 102 and the isolation regions 106, however, other embodiments are possible. This embodiment may provide for improved breakdown performance.

One or more of the isolation regions 106 have a width W₁ at an upper surface or portion (e.g., the opposing surface/portion of the isolation region 106 to the substrate 102). One or more of the isolation regions 106 have a width W₂ at a lower surface or portion (e.g., nearest the substrate 102). The width W₁ is less than the width W₂. In an embodiment, though one or more isolation regions 106 may have a different value W₁ and/or W₂ than each other, each isolation region 106 includes a top portion (W₁) which is narrow than the bottom portion (W₂) nearest the substrate.

One or more of the active regions 104 have a width W₃ at an upper surface or portion (e.g., the opposing surface/portion to the substrate 102). One or more of the active regions 104 have a width W₄ at a lower surface or portion (e.g., nearest the substrate 102). The width W₄ is less than the width W₃. In an embodiment, though one or more active regions 104 may have a different value W₃ and/or W₄, each active region 104 includes a top portion (W₃) which is greater than the bottom portion (W₄) nearest the substrate 102. This may allow for a greater area of active region where a device, for example, transistor or other active device is formed.

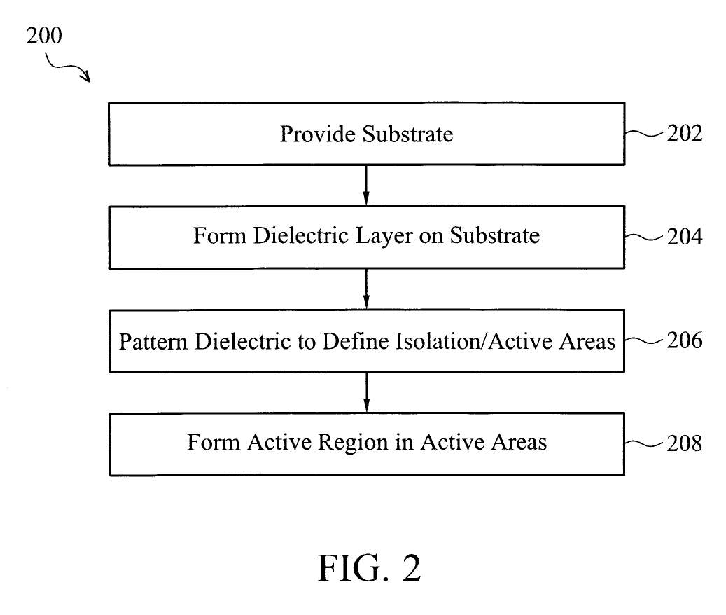

Referring now to FIG. 2, illustrated is a method 200 of forming a semiconductor device. The semiconductor device may include passive components such as resistors, capacitors, inductors, and/or fuses; and active components, such as P-channel field effect transistors (PFETs), N-channel field effect transistors (NFETs), metal-oxide-semiconductor field effect transistors (MOSFETs), complementary metal-oxide-semiconductor transistors (CMOSs), high voltage transistors, and/or high frequency transistors; other suitable components; and/or combinations thereof. It is understood that additional steps can be provided before, during, and after the method 200, and some of the steps described below can be replaced or eliminated, for additional embodiments of the method.

An embodiment of the method 200 may be used in the formation of a semiconductor device such as the semiconductor device 100, described above with reference to FIG. 1. The method 200 begins at block 202 where a substrate is provided. The substrate may be a semiconductor substrate substantially similar to the substrate 102, described above with reference to FIG. 1.

The method 200 then proceeds to block 204 where a dielectric layer is formed on the substrate. The dielectric layer may be an oxide layer. The dielectric layer may be substantially similar to the dielectric layer 104, described above with reference to FIG. 1. The dielectric layer includes material suitable for providing isolation structures, such as STI features.

The method 200 then proceeds to block 206 where the dielectric layer is patterned. The patterning defines region(s) for one or more isolation features (e.g., STI). The patterning further defines region(s) for active areas. The patterning may include removing the dielectric in regions defining the active area(s), while maintaining the dielectric in region(s) defining the isolation structures. The pattern may be provided by patterning a photoresist layer. The patterned photoresist layer is formed by a photolithography process. An exemplary photolithography process may include processing steps of photoresist coating (e.g., spin-on), soft baking, photomask aligning, exposing, post-exposure baking, developing the photoresist, hard baking, and/or other suitable processes. The photolithography exposing process may also be implemented using other suitable methods such as maskless photolithography, electron-beam writing, ion-beam writing, and/or molecular imprint. The etching process may include suitable wet etching and/or dry etching processes using a masking element formed using the above described photolithography process. In an embodiment, block 206 provides isolation features substantially similar to those described above with reference to FIG. 1, including providing a profile that is more narrow on a portion opposing the substrate than the portion nearest the substrate.

The method 200 then proceeds to block 208 where an active region is formed in the regions defining the active area(s). The active region may be formed using an epitaxy process to provide an epitaxially-grown layer on the substrate (e.g., a silicon epitaxial deposition process). The epitaxy process may include vapor-phase epitaxy (VPE), molecular-beam epitaxy (MPE), liquid-phase epitaxy (LPE), and/or other suitable processes. In an embodiment, the epitaxy process is performed at a temperature of approximately 1000° C. The epitaxial layer (epi layer) is grown on the substrate in the regions in which the dielectric layer has been removed (e.g., according to the pattern of block 206). The active regions formed may be substantially similar to the active regions 104, described above with reference to FIG. 1, including having a profile that is wider on a portion opposing the substrate than on a portion nearest the substrate. In an embodiment, the epi layer is a doped epi layer. The epi layer may be doped during its deposition (growth) by adding impurities to the source material of the epitaxy process. The epi layer may be have a gradient doping profile.

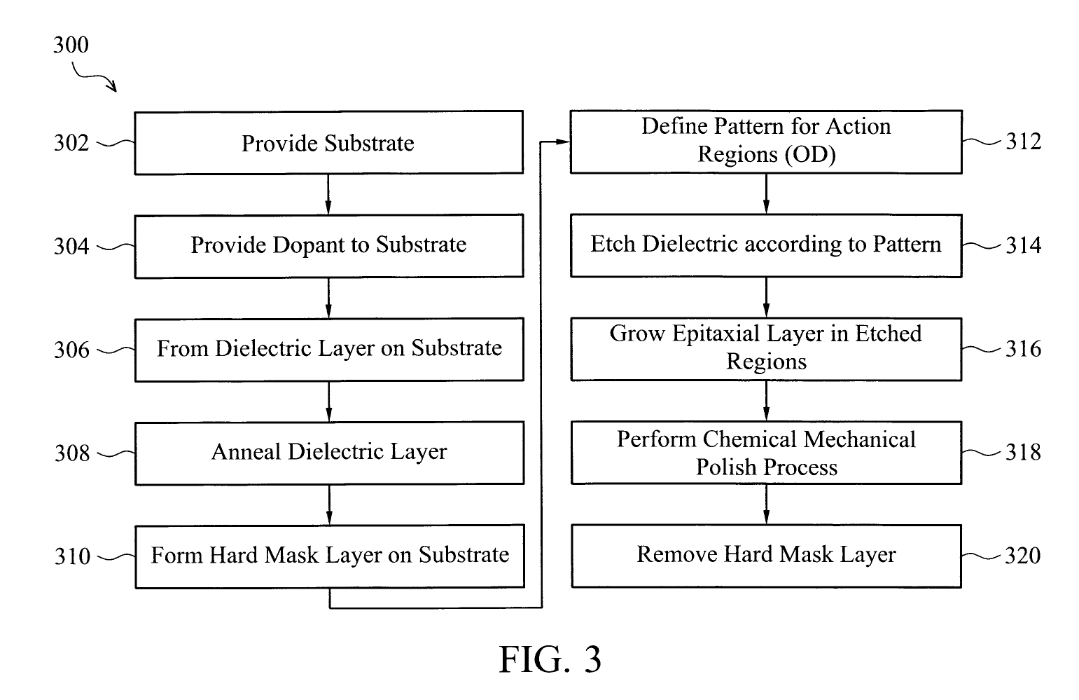

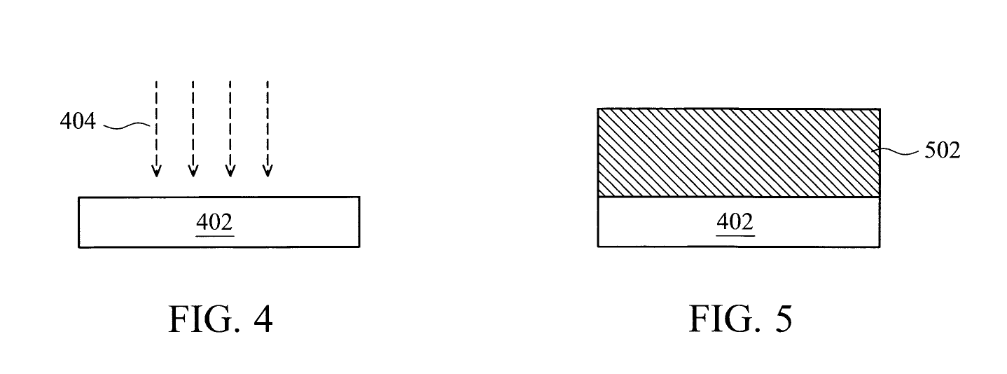

Referring now to FIG. 3, illustrated is a method 300 of forming a semiconductor device. The method 300 may be an embodiment of the method 200. FIGS. 4-11 illustrate exemplary embodiments, shown in cross-sectional views in portion or in entirety, corresponding to one or more steps of the method 300. The semiconductor device formed may include passive components such as resistors, capacitors, inductors, and/or fuses; and active components, such as P-channel field effect transistors (PFETs), N-channel field effect transistors (NFETs), metal-oxide-semiconductor field effect transistors (MOSFETs), complementary metal-oxide-semiconductor transistors (CMOSs), high voltage transistors, and/or high frequency transistors; other suitable components; and/or combinations thereof. It is understood that additional steps can be provided before, during, and after the method 300, and some of the steps described below can be replaced or eliminated, for additional embodiments of the method.

The method 300 begins at block 302 where a substrate is provided. In the example of FIG. 4, a substrate 402 is provided. In an embodiment, the substrate 402 is a silicon substrate. Other examples of the substrate 402 include an elementary semiconductor including silicon and/or germanium in crystal; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; combinations thereof; or other suitable substrate materials. In embodiments, the substrate 402 may be a semiconductor on insulator (SOI) substrate, a strained substrate, and/or include other features known in the art. It is understood that the substrate 402 may include features formed using CMOS technology processing known in the art, and thus are not described in detail herein.

The method 300 then proceeds to block 304 where the substrate is doped. Referring to the example of FIG. 4, a dopant 404 is introduced to the substrate 402. Example dopants include n-type dopant impurities such as phosphorus, arsenic, and/or other suitable materials and p-type dopant impurities such as boron, indium, and/or other suitable materials. The substrate may be doped using ion implantation, diffusion, and/or other suitable processes.

The method 300 then proceeds to block 306 where a dielectric layer is formed on the substrate. In an embodiment, the dielectric layer is an oxide such as silicon oxide. Other examples of materials that may be included in the dielectric layer include any suitable dielectric material including TEOS oxide, silicon nitride, silicon oxynitride, hafnium oxide, zirconium oxide, titanium oxide, aluminum oxide, hafnium dioxide-alumina (HfO₂—Al₂O₃) alloy, PSG, BPSG, other suitable dielectric materials, and/or combinations thereof. The dielectric layer may be a low-k dielectric such as fluorinated silica glass (FSG), carbon doped silicon oxide, Black Diamond® (Applied Materials of Santa Clara, Calif.), Xerogel, Aerogel, amorphous fluorinated carbon, Parylene, BCB (bis-benzocyclobutenes), SiLK (Dow Chemical, Midland, Mich.), polyimide, other proper porous polymeric materials, and/or combinations thereof. The dielectric layer is formed by any suitable process, for example by chemical vapor deposition (CVD), high density plasma CVD, spin-on processing, sputtering, and/or other suitable methods. The dielectric layer may include a multilayer structure comprising multiple dielectric materials. Referring to the example of FIG. 5, a dielectric layer 502 is formed on the substrate 402.

The method 300 then proceeds to block 308 where the dielectric layer is subjected to high temperature processing (e.g., an anneal). Alternatively, block 308 may be omitted.

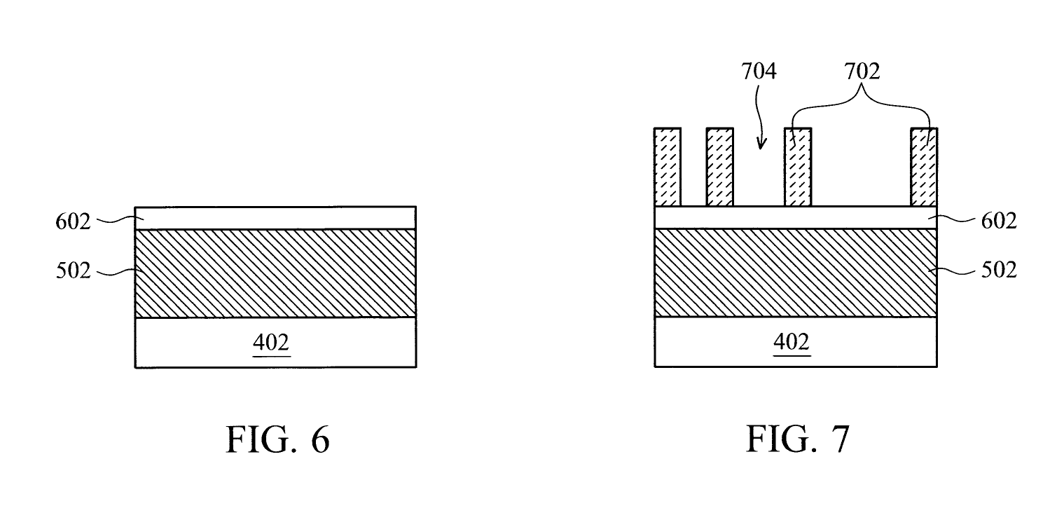

The method 300 then proceeds to block 310 where a hard mask layer is formed on the substrate. The hard mask layer may be formed on the dielectric layer, described above with reference to block 304. In an embodiment, the hard mask layer is silicon nitride. Other examples of hard mask materials include silicon oxynitride, silicon carbide, and/or other suitable materials. The hard mask layer may be formed using any suitable method, such as chemical vapor deposition (CVD), physical vapor deposition (PVD), or sputtering. The hard mask layer may be formed to provide a masking element for patterning of the dielectric layer, as described with reference to blocks 312 and 314. Referring to the example of FIG. 6, the hard mask layer 602 is formed on the dielectric layer 502.

The method 300 then proceeds to block 312 where a pattern for the active regions (OD) is defined on the substrate. The pattern may define the active regions interposed by isolation regions. In an embodiment, the pattern defines shallow trench isolation features. The pattern may be provided by patterning a deposited photoresist layer. The patterned photoresist layer is formed by a photolithography process. An exemplary photolithography process may include processing steps of photoresist coating (e.g., spin-on), soft baking, photomask aligning, exposing, post-exposure baking, developing the photoresist, hard baking, and/or other suitable processes. The photolithography exposing process may also be implemented using other suitable methods such as maskless photolithography, electron-beam writing, ion-beam writing, and/or molecular imprint. Referring to the example of FIG. 7, a patterned photoresist layer 702 is disposed on the substrate 402. The patterned photoresist defines openings 704, which may define active regions to be formed on the substrate 402. The openings 704 expose (leave unprotected) the substrate 402. Examples of the photoresist layer 704 include typical photoresist compositions such as chemical amplification resist (CAR) material. The photoresist layer may include photo-acid generator (PAG) material, a polymer material soluble to a developer when reacted with acid, a solvent, and/or other suitable materials. In an embodiment, the photoresist layer 704 is a multiple-layer resist.

The method 300 then proceeds to block 314 where the dielectric layer is etched according to the pattern provided in block 312. The photoresist layer and/or the hard mask layer (block 310) may be used as a masking element in etching the underlying dielectric layer. A masking element includes any layer or layers used to define a pattern in an underlying layer or layers. The etching process may include a wet etch, dry etch (e.g., plasma etch), and/or other suitable etching process. In an embodiment, the photoresist layer may be used to pattern the underlying hard mask layer, and then the patterned hard mask layer used to pattern the dielectric layer. The photoresist layer may be removed using suitable stripping or ashing processing.

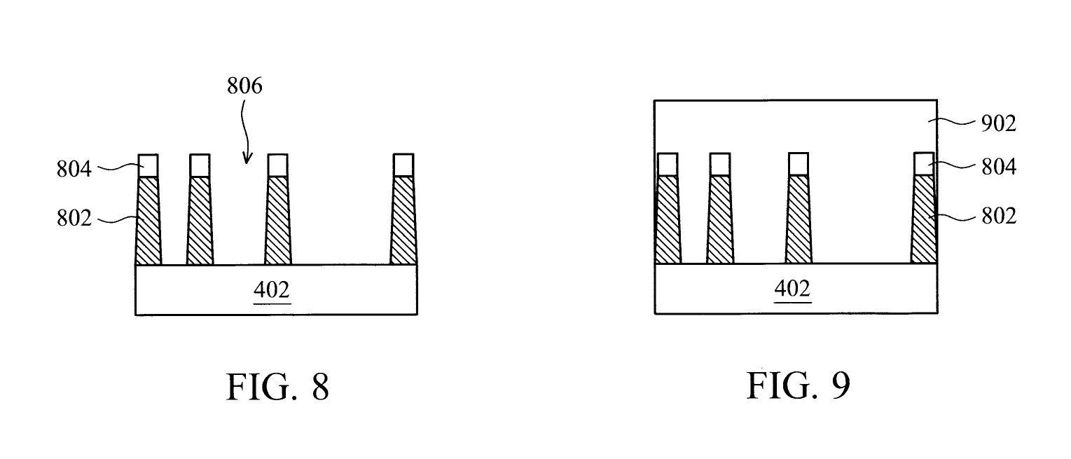

Referring to the example of FIG. 8, the hard mask layer 602 has been etched to form the patterned hard mask layer 804. The patterned hard mask layer 804 protects the dielectric layer in regions that are to provide isolation features. The dielectric layer 502 has been etched to form a plurality of isolation features 802. In an embodiment, the isolation features 802 are shallow trench isolation features. A plurality of openings 806 are also formed. The substrate 402 is exposed in the openings 806. The open areas 806 define an active region of the device.

It is noted that the etching process of block 314 as illustrated in the example of FIG. 8 provides isolation features having a narrower width at a top portion (e.g., opposing the substrate 402) than a bottom portion (e.g., adjacent the substrate 402). The description terms “top” and “bottom” are relative only and do not imply an absolute direction. The isolation features 802 gradually increase in thickness from the top to the bottom. Conversely, the open areas 806 are greater in width at a top portion (e.g., opposing the substrate 402) than at a bottom portion (e.g., adjacent the substrate 402). The open areas 806 are tapered in width from the top to the bottom.

The method 300 then proceeds to block 316 where an active region is formed on the substrate where the dielectric layer has been removed. The active region may be formed by growing an epitaxial layer (epi layer) in the regions where the dielectric layer has been removed. Referring to the example of FIG. 9, an epitaxial layer 902 is provided on the substrate 402. The epitaxial layer is formed by an epitaxy process, which may include vapor-phase epitaxy (VPE), molecular-beam epitaxy (MPE), liquid-phase epitaxy (LPE), and/or other suitable processes. In an embodiment, the epitaxial layer is a doped epi layer. The epitaxial layer may be doped during its formation by adding impurities to the source material of the epitaxy process. The epi layer may be have a gradient doping profile by adding varying amounts and/or types of impurities during the epitaxy process. The gradient doping profile provides varying concentration of dopant impurities through the epitaxial layer.

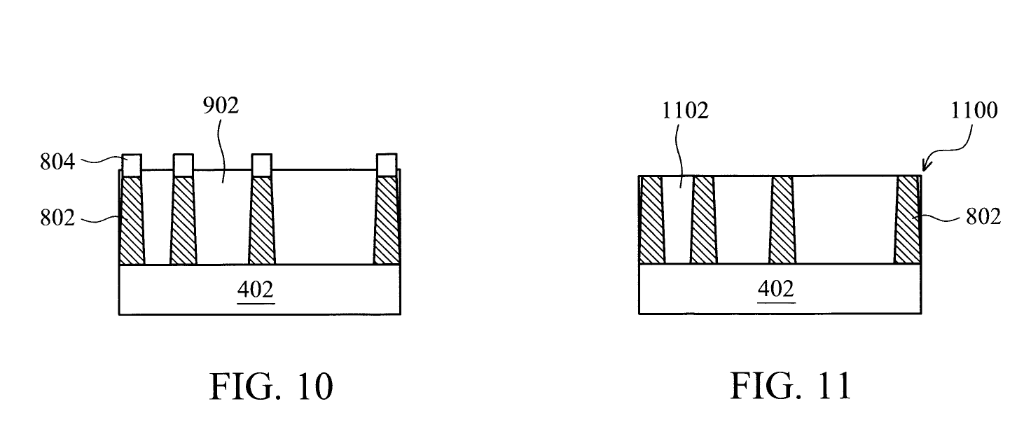

The method 300 then proceeds to block 318 where a chemical mechanical polish (CMP) process is performed. The CMP process provides a planarization of the epitaxial layer. Referring to the example of FIG. 10, after a CMP process, the epitaxial layer 902 overlying the hard mask 804 has been removed.

The method 300 then proceeds to block 320 where the hard mask layer is removed. The hard mask layer may be removed using etching, stripping, ashing, and/or other suitable processes. Referring to the example of FIG. 11, the hard mask layer 804 has been removed leaving a planar surface. Thus, a device 1100 is provided which includes a plurality of active regions 1102, formed by the epitaxial layer 902, interposing a plurality of isolation features 802. One or more devices including active devices such as a transistor may be formed in the active regions 1102. The device 1100 may be substantially similar to the device 100, described above with reference to FIG. 1.

One or more of the embodiments described herein may provide advantages over the conventional processes including, but not limited to, improving the STI feature quality and manufacturability. For example, in conventional approaches, the STI features may be formed by etching trenches into a layer formed on a substrate. The trenches are then filled with isolation material. However, filling the trenches, especially in processes requiring a tighter pitch or spacing of active regions may provide for challenges. For example, voids can form during the filling of the trenches with isolating material. An increased number of process steps may be required such that the STI features are partially filled, etched back, filled again, etched back, and so on. Thus, one or more embodiments described herein may decrease the process steps (e.g., repetition of deposition and etching steps) required to form an STI feature. One or more embodiments described herein may also be advantageous in that they create active regions that have a greater width in the region where active devices are formed (e.g., opposing the substrate), thus, the effective top width of an active (OD) area is increased.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device; comprising:
a substrate;
a shallow trench isolation structure formed on the substrate, wherein the shallow trench isolation structure has a first width at the top of the structure and a second width at the bottom of the structure, wherein the first width is less than the second width; and
an active area adjacent the shallow trench isolation structure.

2. The device of claim 1, wherein the active area has a third width at the top of the active area and a fourth width at the bottom of the active area, wherein the third width is greater than the fourth width.

3. The device of claim 1, wherein the width of the shallow trench isolation structure gradually increases from the first width to the second width.

4. The device of claim 1, wherein the shallow trench isolation structure includes oxide.

5. The device of claim 1, further comprising:
a second shallow trench isolation structure formed on the substrate, wherein the active area interposes the shallow trench isolation structures.

6. The device of claim 1, wherein the active area includes an epitaxially-grown silicon layer.

7. The device of claim 1, wherein the active area includes a gradient dopant profile.

8. The device of claim 7, wherein the gradient dopant profile has a greater dopant concentration adjacent the bottom portion of the shallow trench isolation structure.

9. A method of fabricating a semiconductor device, the method comprising:
providing a substrate;
forming a dielectric layer on the substrate;
etching the dielectric layer, wherein the etching includes forming a first and second shallow trench isolation structures interposed by an exposed substrate region; and
after etching the dielectric layer, growing an epitaxial layer in the exposed substrate region.

10. The method of claim 9, wherein the epitaxial layer forms an active region of the device.

11. The method of claim 9, wherein the etching the dielectric layer includes forming a shallow trench isolation (STI) structure having a first width at a first surface and second width at a second surface opposing the first surface, wherein the first surface is coupled to the substrate, and wherein the first width is greater than the second width.

12. The method of claim 9, wherein the growing the epitaxial layer includes in-situ doping of the epitaxial layer during formation.

13. The method of claim 12, wherein the in-situ doping provides a gradient doping profile in the epitaxial layer.

14. The method of claim 9, wherein the epitaxial layer forms an active region having a first width at a first surface, wherein the first surface is coupled to the substrate, and having a second width at a second surface opposing the first surface, wherein the second width is greater than the first width.

15. A method of fabricating a semiconductor device, the method comprising:
forming a dielectric layer on a semiconductor substrate;
forming a masking element on the semiconductor substrate over the dielectric layer;
etching the dielectric layer according to the pattern, wherein the etching forms a first and a second shallow trench isolation (STI) structure with a first area interposing the first and second STI structures, wherein the first and the second STI structures have a greater width at the bottom than the top of the structures; and
after the etching the dielectric layer, forming an active region in the first area.

16. The method of claim 15, further comprising:
doping the semiconductor substrate prior to forming the dielectric layer.

17. The method of claim 15, wherein the forming the active region includes performing epitaxial growth process.

18. The method of claim 17, wherein the epitaxial process includes in-situ doping.

19. The method of claim 15, further comprising:
forming at least one transistor in the active region.

20. The method of claim 15, wherein the masking element includes a hard mask layer.
